(19) United States
(12) Patent Application Publication
(10) Pub. No.: US 2013/0240039 A1
(43) Pub. Date: Sep. 19, 2013

(54) METHOD FOR MANUFACTURING SOLAR CELLS AND SOLAR CELLS MANUFACTURED THEREBY

(71) Applicant: Rae-Man Park, Daejeon (KR)

(72) Inventor: Rae-Man Park, Daejeon (KR)

(73) Assignee: Electronics and Telecommunications Research Institute, Daejeon (KR)

(21) Appl. No.: 13/989,967

(22) PCT Filed: Nov. 25, 2011
(86) PCT No.: PCT/KR2011/009060

§ 371 Date: May 28, 2013

(30) Foreign Application Priority Data
Nov. 30, 2010 (KR) 10-2010-0120775
Nov. 11, 2011 (KR) 10-2011-0117534

(51) Int. Cl. H01L 31/18; H01L 31/032

(52) U.S. Cl. CPC H01L 31/1892; H01L 31/0322
USPC 136/262; 438/94

(57) ABSTRACT

The present invention provides a method for manufacturing solar cells and the solar cells manufactured thereby. The method is capable of manufacturing flexible solar cells simply, by attaching a flexible substrate on a second electrode after forming multiple layers such as a copper indium gallium selenide (CIGS) absorption layer on a sacrificial substrate under a high temperature process. Additionally, a separation film is removed by a laser or by selective wet etching after the attachment of the flexible substrate. Therefore, flexible CIGS solar cells having high efficiency can be achieved.

### TECHNICAL FIELD

The present invention relates to a method of manufacturing a solar cell and a solar cell manufactured by the same.

### BACKGROUND ART

Copper indium gallium selenide (Cu—In—Ga—Se or CIGS) thin-film solar cells have high efficiency and high stability without initial deterioration when compared to amorphous silicon solar cells, and technology for utilizing the CIGS thin-film solar cells is being developed. Due to excellent properties of CIGS thin-film solar cells, initial studies are being conducted on CIGS thin-film solar cells for light-weight and high-efficiency space solar cells to be used as a substitute for conventional monocrystal silicon (200 Watts/kilogram (W/kg)) solar cells. CIGS thin-film solar cells generate electricity per weight of 100 W/kg, far superior to existing silicon or GaAs solar cells producing 20 to 40 W/kg. Currently, CIGS thin-film solar cells exhibit a 20.3% efficiency by co-evaporation, equivalent to conventional polycrystal silicon solar cells having a peak efficiency of 20.3%.

The use of a flexible substrate as a substrate of a solar cell is required, because solar cells have excellent processibility when the flexible substrate is used and thus, are easily formed into various shapes. Accordingly, marketability of the solar cells improves and a reduction in price increases competitiveness. However, most flexible materials are formed of polymers, which are easily melted or deformed by heat. A CIGS optical absorption layer is formed at about 550 to 600° C. to have high efficiency, whereas the flexible substrate is unable to endure such temperatures. Thus, manufacturing a solar cell having both a high-efficiency CIGS optical absorption layer and a flexible substrate is difficult.

### DISCLOSURE OF INVENTION

### Technical Goals

An aspect of the present invention provides a method of manufacturing a copper indium gallium selenide (CIGS) solar cell having high efficiency and flexibility.

Another aspect of the present invention provides a CIGS solar cell having high efficiency and flexibility.

### Technical Solutions

According to an exemplary embodiment, there is provided a method of manufacturing a solar cell including forming a release layer on a sacrificial substrate, forming a first electrode, an optical absorption layer, a buffer layer, a window layer, and a second electrode, sequentially, on the release layer, forming a flexible substrate on the second electrode, and removing the release layer to detach the sacrificial substrate from the first electrode, wherein the release layer is formed from a gallium oxide nitride (GaOₓN_{y}) layer, where 0<x<1 and 0<y<1.

The removing of the release layer may include melting the release layer using an ultraviolet laser in a range of 400 to 650 millijoules/square centimeter (mJ/cm²). The ultraviolet laser may be a krypton fluoride (KrF) excimer laser.

The removing of the release layer may include conducting a wet etching process of selectively removing the release layer using an alkaline solution. The alkaline solution may be ammonia water.

The forming of the flexible substrate may include disposing an adhesive layer on the second electrode to bond the flexible substrate.

The forming of the release layer may use at least one selected from the group consisting of sputtering, chemical vapor deposition process and wet deposition process.

The flexible substrate may have a light transmittance of 80% or higher.

The release layer may further include sodium added into the gallium oxide nitride (GaOₓN_{y}) layer. Sodium may be included in an amount of 0.1 to 10 at. %.

The forming of the optical absorption layer may use at least one selected from the group consisting of co-evaporation, sputtering, electrode position, and printing.

According to another exemplary embodiment, there is provided a method of manufacturing a solar cell including forming a release layer on a sacrificial substrate, sequentially forming a first electrode, an optical absorption layer, a buffer layer, a window layer, and a second electrode on the release layer, forming a flexible substrate on the second electrode, and removing the release layer to detach the sacrificial substrate from the first electrode, wherein the release layer includes 0.1 to 10 at. % of sodium.

According to still another exemplary embodiment, there is provided a solar cell including a first electrode, an optical absorption layer on the first electrode, a buffer layer on the optical absorption layer, a window layer on the buffer layer, a second electrode on the window layer, an adhesive layer on the second electrode, and a flexible substrate on the adhesive layer.

The flexible substrate may include a polymer film having flexibility and a transmittance of 80% or higher. The flexible substrate may include ethylene vinyl acetate.

### Advantageous Effects

According to an exemplary embodiment of the present invention, a method of manufacturing a solar cell forms a first electrode and an optical absorption layer on a sacrificial substrate, such that when the sacrificial substrate is a glass substrate, the sacrificial substrate is able to endure a high temperature in a temperature range of 550 to 660° C. as an optimal process temperature at which the copper indium gallium selenide (CIGS) optical absorption layer is formed, thereby forming a high-quality CIGS optical absorption layer. Further, as sodium is properly added to a release layer, sodium diffuses to the CIGS optical absorption layer through the first electrode while the first electrode and the CIGS optical absorption layer are formed, and accordingly a volume of grains in the CIGS optical absorption layer increases. As a result, light absorptance improves and a photoelectric conversion rate increases, thereby realizing a high-efficiency solar cell.

After forming a plurality of layers including the CIGS optical absorption layer at a high process temperature, a flexible substrate is attached to a second electrode, thereby allowing for simple manufacturing a flexible solar cell. Accordingly, the solar cell may be easily formed into various shapes to enhance marketability and to reduce a price, thereby raising competitiveness the solar cell.

Since the release layer is removed by a laser or selective wet etching after attaching the flexible substrate, heat may not be released and thus, damage to the flexible substrate is avoided. Accordingly, a high-efficiency flexible solar cell may be realized. Further, since a high-temperature process is not involved, the flexible substrate has fewer constraints of materials and thus, various polymer films may be used for the flexible substrate.

Further, the separated sacrificial substrate is recycled to reduce manufacturing expenses.

### BRIEF DESCRIPTION OF DRAWINGS

FIG. 1 is a flowchart illustrating a method of manufacturing a solar cell according to an exemplary embodiment of the present invention;

FIGS. 2 through 5 are cross-sectional views illustrating a sequential method of manufacturing a solar cell according to an exemplary embodiment of the present invention;

FIG. 6 is a cross-sectional view of a solar cell manufactured according to an exemplary embodiment of the present invention; and

FIG. 7 is a cross-sectional view of a solar cell manufactured according to another exemplary embodiment of the present invention.

### BEST MODE FOR CARRYING OUT THE INVENTION

Hereinafter, exemplary embodiments of the present invention will be described in detail with reference to the accompanying drawings. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. Other spatially relative terms, such as “between,” “directly between,” and the like, used herein to describe the relationship between elements may be understood in a similar manner.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section, and vice versa without departing from the teachings of the present invention.

As used herein, the singular forms “a”, “an” and “the” are intended to include the plural forms as well, unless the context clearly indicates otherwise. It will be further understood that the terms “comprises,” “includes,” “comprising,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. As used herein, the expression “at least one” may have the same meaning as a minimum of one and selectively mean one or more than one.

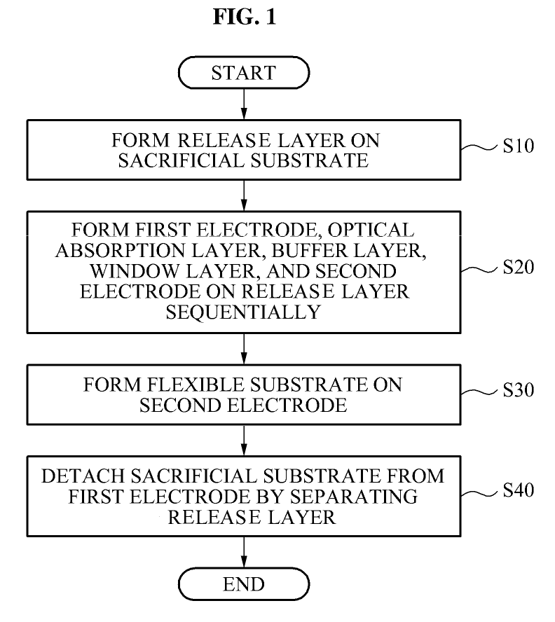

FIG. 1 is a flowchart illustrating a method of manufacturing a solar cell according to an exemplary embodiment of the present invention.

Referring to FIG. 1, the method of manufacturing the solar cell according to the present embodiment includes forming a release layer on a sacrificial substrate (S10), forming a first electrode, an optical absorption layer, a buffer layer, a window layer and a second electrode, sequentially, on the release layer (S20), forming a flexible substrate on the second electrode (S30), and removing the release layer to detach the sacrificial substrate from the first electrode (S40).

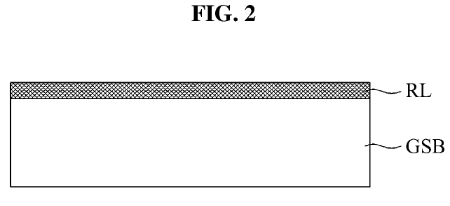

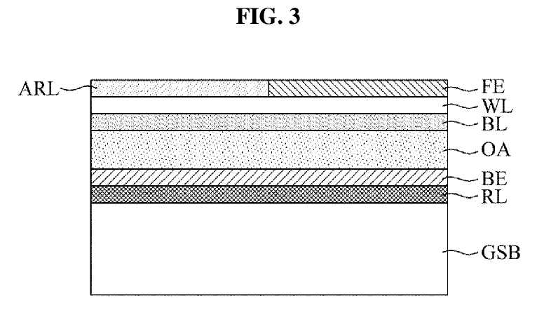

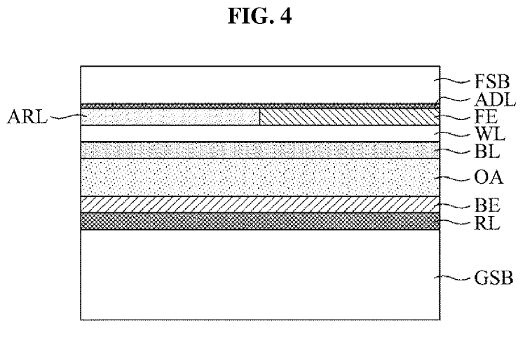

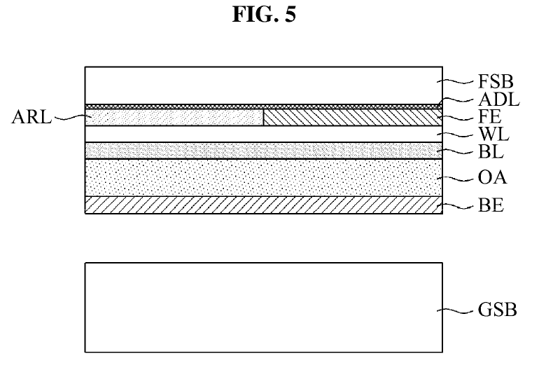

FIGS. 2 to 5 are cross-sectional views illustrating a sequential method of manufacturing a solar cell according to an exemplary embodiment of the present invention.

Referring to FIGS. 1 and 2, a release layer RL is formed on a sacrificial substrate GSB. The sacrificial substrate may be a soda-lime glass substrate. The release layer RL may be formed from a gallium oxide nitride (GaOₓN_{y}) layer, where 0<x<1 and 0<y<1. The release layer RL may be formed by at least one selected from the group consisting of sputtering, chemical vapor deposition and wet deposition.

When the release layer RL is formed by sputtering, a gallium oxide (Ga₂O₃) layer target is subjected to radio frequency (RF) sputtering at room temperature in a nitrogen gas atmosphere. Alternatively, when the release layer RL is formed by sputtering, a gallium oxide nitride (GaOₓN_{y}) layer target is subjected to pulse direct current (DC) sputtering at 200° C. or lower in an argon gas atmosphere. Here, a sputtering plasma power is adjusted to 100 to 200 Watts (W), and a gas pressure is adjusted to 2 to 50 milliToor (mTorr).

The release layer RL may further include sodium added into the gallium oxide nitride (GaOₓN_{y}) layer. Sodium may be included in an amount of 0.1 to 10 at %. To form the release layer LR to include sodium, the gallium oxide (Ga₂O₃) layer target or the gallium oxide nitride (GaOₓN_{y}) layer target may include sodium.

When the release layer RL is formed by chemical vapor deposition, trimethylgallium or triethylgallium is subjected to deposition in a mixed gas atmosphere of oxygen and nitrogen, as a preferred metalorganic source. Deposition is carried out in a range of room temperature to 500° C. and a gas pressure in a range of 10 mTorr to 100 Torr.

When the release layer RL is formed by wet deposition, a metal source soluble in water or alcohol, such as gallium chloride (GaCl₃) and gallium iodide (GaI₃) is subjected to deposition to form a gallium oxide (GaOₓ) thin film, followed by nitriding and heat treatment in an ammonia gas atmosphere, or a gallium oxide nitride (GaOₓN_{y}) thin film is formed in a mixed gas atmosphere of oxygen and ammonia in a deposition chamber or a quartz tube. Nitriding may include the heat treatment, which may be carried out in a temperature range of 100 to 500° C.

Referring to FIGS. 1 to 3, after depositing the release layer RL, a first electrode BE, an optical absorption layer OA, a buffer layer BL, a window layer WL and a second electrode FE are formed, sequentially, on the release layer RL (S20). The first electrode BE preferably has a low specific resistance, and excellent adhesion to the release layer RL so as not to allow peeling due to a difference in expansion coefficients. The first electrode BE may be formed with a molybdenum (Mo) thin film. The first electrode BE may be deposited by sputtering.

The optical absorption layer OA may generate electrons and holes using light energy. The optical absorption layer OA may produce electricity from light energy through the photoelectric effect. The optical absorption layer OA may include any one chalcopyrite semiconductor selected from the group consisting of copper indium selenide (CuInSe), CuInSe₂, copper indium gallium selenide (CuInGaSe) and CuInGaSe₂. Chalcopyrite semiconductors may have a band gap of about 1.2 electron volts (eV).

The optical absorption layer OA may be formed by at least one selected from the group consisting of co-evaporation, sputtering, electrodeposition and printing. The optical absorption layer OA may be deposited in a temperature range of 550 to 600° C. While the optical absorption layer OA is deposited, sodium included in the release layer RL diffuses into the optical absorption layer OA through the first electrode BE. Accordingly, grains in the optical absorption layer OA grow larger. As a result, light absorptance of the optical absorption layer OA improves and a photoelectric conversion rate thereof increases, thereby realizing a high-efficiency solar cell.

The buffer layer BL may buffer band gaps of the window layer WL and the optical absorption layer OA. The buffer layer BL may have a band gap larger than that of the optical absorption layer OA and smaller than that of the window layer WL. For example, the buffer layer BL may be formed with a cadmium sulfide (CdS) or zinc sulfide (ZnS) thin film. CdS may have a constant band gap of about 2.4 eV. The buffer layer BL may be formed by chemical bath deposition. The buffer layer BL may prevent damage to the optical absorption layer OA when the window layer is formed. The buffer layer BL may be provided for favorable bonding of the optical absorption layer OA and the window layer WL since the optical absorption layer OA and the window layer WL have different lattice constants. For example, the buffer layer BL may have a hexagonal crystal structure.

The window layer WL may transmit as much light as possible, absent reflection. The window layer WL may be formed with an aluminum or gallium-doped zinc oxide (ZnO) or indium tin oxide (ITO) thin film. The window layer WL may be generally formed by sputtering, chemical vapor deposition, or atomic thin layer deposition.

The second electrode FE may include at least one of aluminum and nickel. The second electrode FE may be formed by sputtering. The second electrode FE may be formed in various forms, for example, a grid form.

Before the second electrode FE is formed, an antireflection layer ARL may be formed on the window layer WL. Forming the antireflection layer ARL is not essential, and is optional. The antireflection layer ARL may be formed with magnesium fluoride (MgF₂). The antireflection layer ARL may be formed by evaporation. The antireflection layer ARL may be formed selectively in a region where the second electrode FE is not formed.

Referring to FIGS. 1 to 4, a flexible substrate FSB is formed on the second electrode FE and the antireflection layer ARL. The flexible substrate FSB may be bonded to the second electrode FE via an adhesive layer ADL. The flexible substrate FSB may include a polymer film having flexibility and a transmittance of 80% or higher. For example, the flexible substrate FSB may include ethylene vinyl acetate. The flexible substrate FSB and the adhesive layer ADL may be formed using a polymer tape.

An additional adhesive film may be formed on the flexible substrate FSB, thereby manufacturing an adhesive solar cell.

Referring to FIGS. 1 to 5, the release layer BL is removed to detach the sacrificial substrate GSB from the first electrode BE. The release layer BL may be removed by a laser or by wet etching. To remove the release layer BL using a laser, only the release layer BL is melted using an ultraviolet laser through the sacrificial substrate GSB. The ultraviolet laser may be preferably a 248 nanometer (nm) KrF excimer laser. Scanning is carried out at an output of 300 to 800 mJ/cm² and at a frequency of 10 to 60 Hertz (Hz) in a pulse mode. Here, a scan speed is associated with a size of a laser beam, for example, about 1 to 50 millimeters/second (mm/sec) in a beam size of 1.5×1.5 mm². To remove the release layer BL by wet etching, the release layer BL is immersed in an alkaline solution or particular portion of the release layer BL is sprayed with the alkaline solution, thereby selectively removing the release layer BL. Here, the alkaline solution may be ammonia water. The alkaline solution may have a pH of about 8 to 12. In wet etching, the release layer BL may be removed by immersing in the alkaline solution for 30 to 300 seconds or spraying the alkaline solution intensively onto the release layer BL. Here, a spraying speed is in a range of 1 to 100 liters/minute (l/min). The sacrificial substrate GSB separated by removing the release layer BL may be recycled, thereby reducing manufacturing expenses.

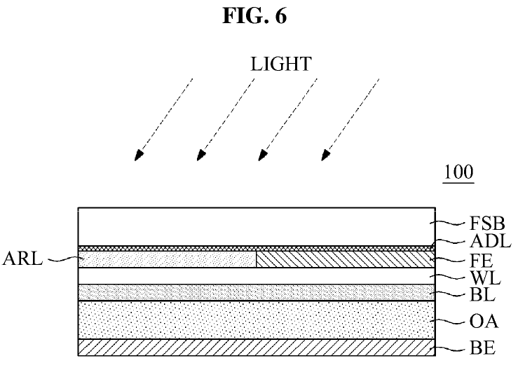

FIG. 6 is a cross-sectional view of a solar cell manufactured according to an exemplary embodiment of the present invention.

Referring to FIG. 6, the solar cell 100 manufactured according to the exemplary embodiment of the present invention includes an optical absorption layer OA, a buffer layer BL, a window layer WL and a second electrode FE on a first electrode BE. The second electrode FE is disposed on a portion of the window layer WL, and a portion of the window layer WL is covered by an antireflection layer ARL. An adhesive layer ADL and a flexible substrate FSB are sequentially deposited on the antireflection layer ARL and the second electrode FE. Light enters the flexible substrate FSB. The entering light reaches the optical absorption layer OA, passing through the second electrode FE, the window layer WL and the buffer layer OA. The solar cell generates electrons and holes using light energy transmitted through the optical absorption layer OA, thereby producing electricity through the photoelectric effect. The electricity produced is collected in the second electrode FE.

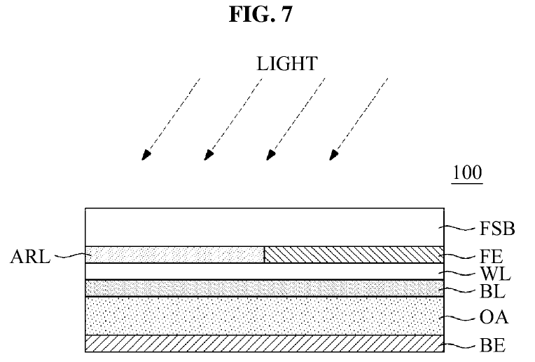

FIG. 7 is a cross-sectional view of a solar cell manufactured according to another exemplary embodiment of the present invention.

Referring to FIG. 7, the solar cell 101 according to the present embodiment does not include the adhesive layer ADL. The flexible substrate FSB may be in contact with both the antireflection layer ARL and the second electrode FE. Here, the flexible substrate FSB may be formed on the second electrode FE through deposition, printing or coating/curing, instead of being bonded using the adhesive layer ADL.

Although the present invention has been shown and described with reference to a few exemplary embodiments, these embodiments are provided for illustrative purposes only and are not to be in any way construed as limiting the present invention. Instead, it would be appreciated by those skilled in the art that changes and modifications may be made to these embodiments without departing from the principles and spirit of the invention, the scope of which is defined by the claims and their equivalents.

1. A method of manufacturing a solar cell comprising:
forming a release layer on a sacrificial substrate;
forming a first electrode, an optical absorption layer, a buffer layer, a window layer, and a second electrode, sequentially, on the release layer;
forming a flexible substrate on the second electrode; and
removing the release layer to detach the sacrificial substrate from the first electrode,
wherein the release layer is formed from a gallium oxide nitride (GaOxNy) layer, where 0<x<1 and 0<y<1.

2. The method of claim 1, wherein the removing of the release layer comprises melting the release layer using an ultraviolet laser.

3. The method of claim 2, wherein the ultraviolet laser is a krypton fluoride (KrF) excimer laser.

4. The method of claim 1, wherein the removing of the release layer comprises conducting a wet etching process of selectively removing the release layer using an alkaline solution.

5. The method of claim 4, wherein the alkaline solution is ammonia water.

6. The method of claim 1, wherein the release layer further comprises 0.1 to 10 at. % of sodium added into the gallium oxide nitride (GaOₓN_{y}) layer.

7. The method of claim 6, wherein the sodium comprised in the release layer diffuses to the optical absorption layer through the first electrode while the optical absorption layer is formed.

8. The method of claim 1, wherein the optical absorption layer comprises at least copper, indium and selenium.

9. The method of claim 1, wherein the forming of the flexible substrate comprises disposing an adhesive layer on the second electrode to bond the flexible substrate.

10. The method of claim 1, wherein the flexible substrate has a light transmittance of 80% or higher.

11. A method of manufacturing a solar cell comprising:
forming a release layer on a sacrificial substrate;
forming a first electrode, an optical absorption layer, a buffer layer, a window layer, and a second electrode, sequentially, on the release layer;
forming a flexible substrate on the second electrode; and
removing the release layer to detach the sacrificial substrate from the first electrode,
wherein the release layer comprises 0.1 to 10 at. % of sodium.

12. A solar cell comprising:
a first electrode;
an optical absorption layer on the first electrode;
a buffer layer on the optical absorption layer;
a window layer on the buffer layer;
a second electrode on the window layer;
an adhesive layer on the second electrode; and
a flexible substrate on the adhesive layer, wherein the optical absorption layer comprises sodium.

13. The solar cell of claim 12, wherein the flexible substrate comprises a polymer film having flexibility and a light transmittance of 80% or higher.

14. The solar cell of claim 13, wherein the flexible substrate comprises ethylene vinyl acetate.
